(19) United States
(12) Patent Application Publication
(10) Pub. No.: US 2013/0020699 A1
(43) Pub. Date: Jan. 24, 2013

(54) PACKAGE STRUCTURE AND METHOD FOR FABRICATING THE SAME

(71) Applicant: Tung-Hsien HSIEH, Zhubei City (TW)

(72) Inventor: Tung-Hsien HSIEH, Zhubei City (TW)

(73) Assignee: MEDIATEK INC., Hsin-Chu (TW)

(21) Appl. No.: 13/479,030

(22) Filed: May 23, 2012

Related U.S. Application Data
(60) Provisional application No. 61/504,765, filed on Jul. 6, 2011.

(51) Int. Cl. H01L 23/498; H01L 21/56

(52) U.S. Cl. 257/737; 438/124; 257/E23.068; 257/E21.502

(57) ABSTRACT

The invention provides a package structure, including: a substrate, wherein the substrate has a first surface and a second surface, and a first pattern metal layer is formed on the first surface, and a second patterned metal layer is formed on the second surface, and the substrate has a plurality of vias formed therein, wherein the first patterned metal layer is electrically connected to the second patterned metal layer through the plurality of vias, and the widths of the plurality of vias are gradually increased from the first surface to the second surface; a chip formed on the first surface of the substrate; and a molding material is formed on the substrate and the chip, wherein the chip is covered by the molding material.

### CROSS REFERENCE TO RELATED APPLICATIONS

This application claims the benefit of U.S. Provisional Application No. 61/504,765, filed Jul. 6, 2011, the entirety of which is incorporated by reference herein.

### BACKGROUND OF THE INVENTION

1. Field of the Invention

The present invention relates to a package structure, and in particular relates to a package structure with a bump of a chip on a via and method for fabricating the same.

2. Description of the Related Art

Recently, driven by the fast development of electrical industries, the aim of integrated circuit (IC) design has been to achieve high-level integration or miniaturization.

FIG. 1 shows a cross section of a conventional package structure. The package structure 10 comprises: a substrate 12; a chip 30 formed on the substrate; and a molding material 35 formed on the substrate 12 and the chip 30. The substrate 12 has a first surface 12a and a second surface 12b, a first patterned metal layer 14 is formed on the first surface 12a, a second patterned metal layer 16 is formed on the second surface 12b, and the substrate 12 has a plurality of vias 18 formed therein. The chip 30 has a plurality of first solder bumps 32 facing the first surface 12a of the substrate 12, wherein the first solder bump 32 is electrically connected to the first metal layer 14, and the first metal layer 14 is electrically connected to the second patterned metal layer 16 through the plurality of vias 18. The package structure 10 further comprises an anti-soldering insulation layer 20 formed on the fist patterned metal layer 14 and the second patterned metal layer 16, and a second solder bump 22 formed on the second patterned metal layer 16.

Note that the first solder bump 32 of the chip 30 is not formed on the vias 18, thus, in order to electrically connect to the first solder bump 32 and the vias 18, a longer trace route is formed (e.g. the fist patterned metal layer 14 with a longer length). However, the longer trace route may degrade the electrical performance of the package structure 10.

In order to improve the electrical performance, another package structure 10a is provided. FIG. 2 shows another cross section of a conventional package structure wherein like elements are identified by the same reference numbers as in FIG. 1, and thus are omitted for clarity. Note that in FIG. 2, the first solder bump 32 of the chip 30 is directly formed on the vias 18. The package structure 10a is formed by the following steps. A via hole is formed in the substrate by a mechanical drilling method, and vias are formed by filling a metal material in the via hole. Then, a first patterned metal layer 14 is formed on the vias 18. Next, an anti-soldering insulation layer 20 is formed on the first patterned metal layer 14, wherein the anti-soldering insulation layer 20 has a plurality of openings 25 to expose the first patterned metal layer 14. Because the first patterned metal layer 14 is formed by an electroplating process, the exposed first patterned metal layer 14 in the opening 25 often has dimple shapes (uneven surfaces). Thus, a faulty electrically connection between the dimple-shaped first patterned metal layer 14 and the first solder bump 32 occurs.

Accordingly, there is a need to develop a package structure which can solve the faulty connection caused by the dimple-shaped first patterned metal layer.

### BRIEF SUMMARY OF THE INVENTION

The present invention provides a package structure, comprising: a substrate, wherein the substrate has a first surface and a second surface, and a first pattern metal layer is formed on the first surface, and a second patterned metal layer is formed on the second surface, and the substrate has a plurality of vias formed therein, wherein the first patterned metal layer is electrically connected to the second patterned metal layer through the plurality of vias, and the widths of the plurality of vias are gradually increased from the first surface to the second surface; a chip formed on the first surface of the substrate, wherein the chip has a plurality of bumps facing the first surface of the substrate, and the bumps are formed on the vias and are electrically connected to the first patterned metal layer; and a molding material is formed on the substrate and the chip, wherein the chip is covered by the molding material.

The present invention also provides a method for fabricating the package structure, comprising: providing a substrate, wherein the substrate has a first surface and a second surface, and a first pattern metal layer is formed on the first surface, and a second patterned metal layer is formed on the second surface, and the substrate has a plurality of vias formed therein, wherein the first patterned metal layer is electrically connected to the second patterned metal layer through the plurality of vias, and the widths of the plurality of vias are gradually increased from the first surface to the second surface; forming a chip on the fist surface of the substrate, wherein the chip has a plurality of bumps facing the first surface of the substrate, and the bumps are formed on the vias and are electrically connected to the first patterned metal layer; and forming a molding material on the substrate and the chip, wherein the chip is covered by the molding material.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 shows a cross-sectional schematic representation of conventional package structures;

FIG. 2 shows a cross-sectional schematic representation of conventional package structures;

FIG. 3A-3E show cross-sectional schematic representations of various stages of fabricating a package structure in accordance with embodiments of the invention; and

FIG. 4 shows a cross-sectional schematic representation of a package structure in accordance with an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

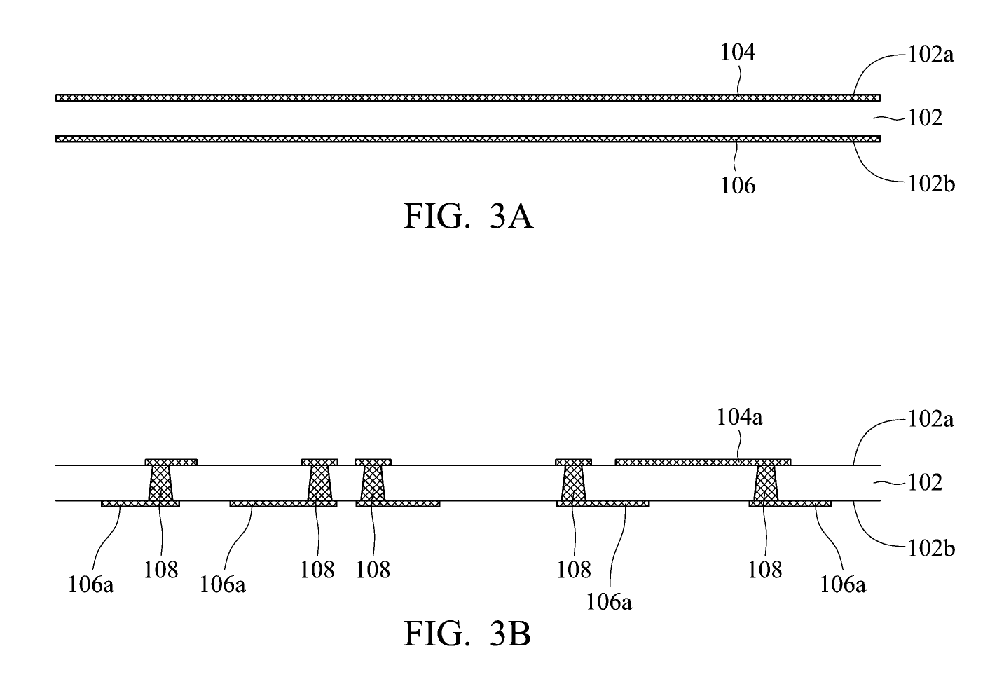

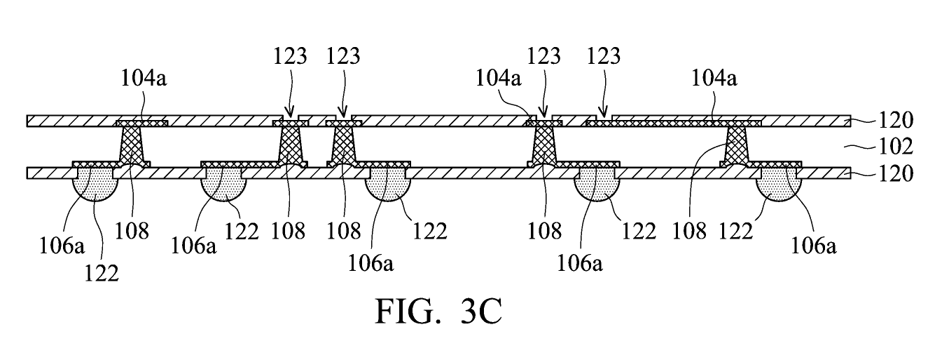

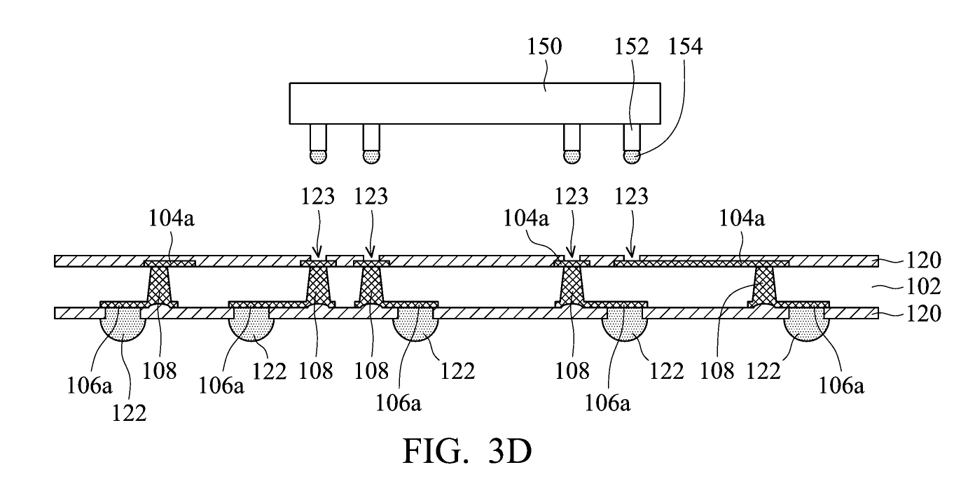

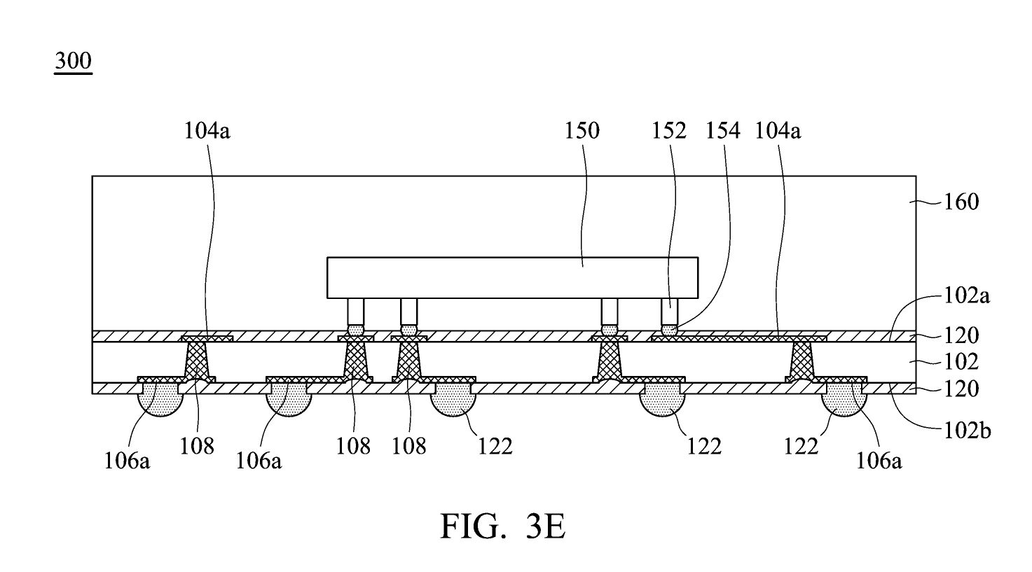

The following descriptions of FIG. 3A to FIG. 3E are used to describe a fabrication method of a package structure of the invention. The drawings are idealized representations for better illustration of the methods of the invention, and various elements are not necessarily shown to scale.

Referring to FIG. 3A, a substrate 102 is provided. The substrate 102 has a first surface 102a and a second surface 102b. A first metal layer 104 is formed on the first surface 102a, and a second metal layer 106 is formed on the second surface 104b. The substrate 102 comprises paper phenolic resin, composite epoxy, polyimide resin or glass fiber. The first metal layer 104 and the second metal layer 106 may be formed by sputtering, laminating, coating or other well-known methods. The first metal layer 104 and the second metal layer 106 each individually comprise copper, alumina, nickel, gold or combinations thereof.

In one embodiment, a double-sided copper clad laminate substrate 102 is provided with a core material of paper phenolic resin and copper foil formed on the first surface 102a and the second surface 102b.

Referring to FIG. 3B, a plurality of via holes (before filling in the metal materials) are formed in the substrate 102, and the vias are formed by filling the metal materials in the via holes. Then, a first patterned metal layer 104a and a second patterned metal layer 106a are individually formed on the first surface 102a and the second surface 102b by a photolithography process. The photolithography process comprises coating of a photoresist, developing, etching and stripping.

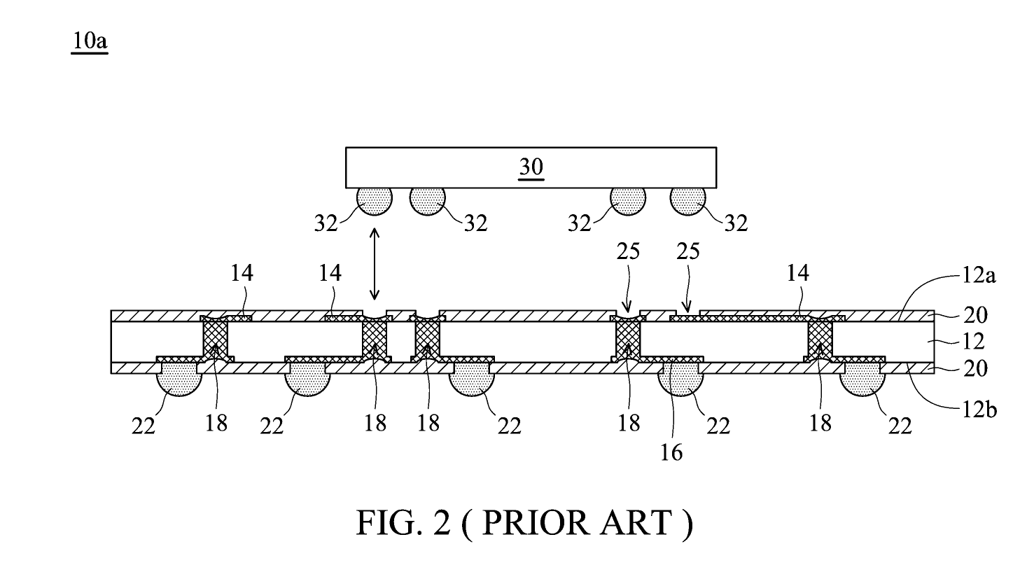

Note that in FIG. 3B, the vias 108 are formed by a laser drilling method and the laser light is irradiated from the second surface 102b of the substrate 102. Thus, the widths of the plurality of vias 108 are gradually increased from the first surface 102a to the second surface 102b. Additionally, by controlling the energy of the laser light, the first patterned metal layer 104a is not punched through by the laser light, and thus the flat-shaped surface of the first patterned metal layer 104a is preserved. Therefore, the dimple-shaped first patterned metal layer 14 in FIG. 2 does not occur in the invention.

In the prior art, a pre-solder is often added on the dimple-shaped first patterned metal layer 14 to fill the dimple defects. Compared with the prior art, because the first patterned metal layer 104a has the flat-shaped surface, there is no need to form any pre-solder. Thus, the manufacturing cost and time can be reduced.

In one embodiment, a CO₂ laser drilling process is preferred. Under increased power and steady discharge, a CO₂ laser is produced by doping of other gases, such as N₂, He or CO. The energy of the CO₂ laser light may be controlled according to the thickness of the substrate 102.

In another embodiment, an Nd:YAG laser process is utilized. In yet another embodiment, a UV laser process is utilized.

Then, resin smear produced by laser drilling is cleaned by the well-known desmear process.

Then, referring to FIG. 3C, the anti-soldering insulation layer 120 is individually formed on the first patterned metal layer 104a and the second patterned metal layer 106a.

The anti-soldering insulation layer 120 is formed by an anti-soldering material, such as green paint. The function of the anti-soldering insulation layer 120 is to protect the the buried metal layers, and to prevent oxidation or short-circuit welding of the buried metal layers.

Furthermore, a plurality of the first opening 123 is formed in the anti-soldering insulation layer 120 to expose the first patterned metal layer 104a by a photolithography process. The photolithography process comprises coating of a photoresist, developing, etching and stripping. A plurality of the second openings (not shown in FIG. 3C) is formed in the anti-soldering insulation layer 120 to expose the second patterned metal layer 106a, and a plurality of bumps 122 are formed in the second opening to electrically connect to the second patterned metal layer 106a.

Note that compared with the prior art, it is not needed to form the pre-solder in the opening 123 and on the first patterned metal layer 104a due to the flat-shaped surface of the first patterned metal layer 104a.

Referring to FIG. 3D, a chip 150 is provided. The chip 150 has a plurality of metal pillar bumps 152, and the solder 154 is formed on the metal pillar bumps 152. The function of the solder 154 is to help strengthen the bonding between the metal pillar bumps 152 and the first patterned metal layer 104a.

In one preferred embodiment, the metal pillar bumps are cupper pillar bumps. In addition to cupper (Cu), other conductive materials such as nickel (Ni), gold (Au) or palladium (Pd) and the like may be used, and the alloys of these materials may also be used.

Then, FIG. 3E shows a cross-sectional schematic representation of a package structure 300 in accordance with an embodiment of the invention. The chip 150 is formed on the substrate 102, and a molding structure 160 is formed on the substrate 102 and the chip 150, wherein the chip 150 is covered by the molding material 160 to protect the chip 150 and the buried metal layers.

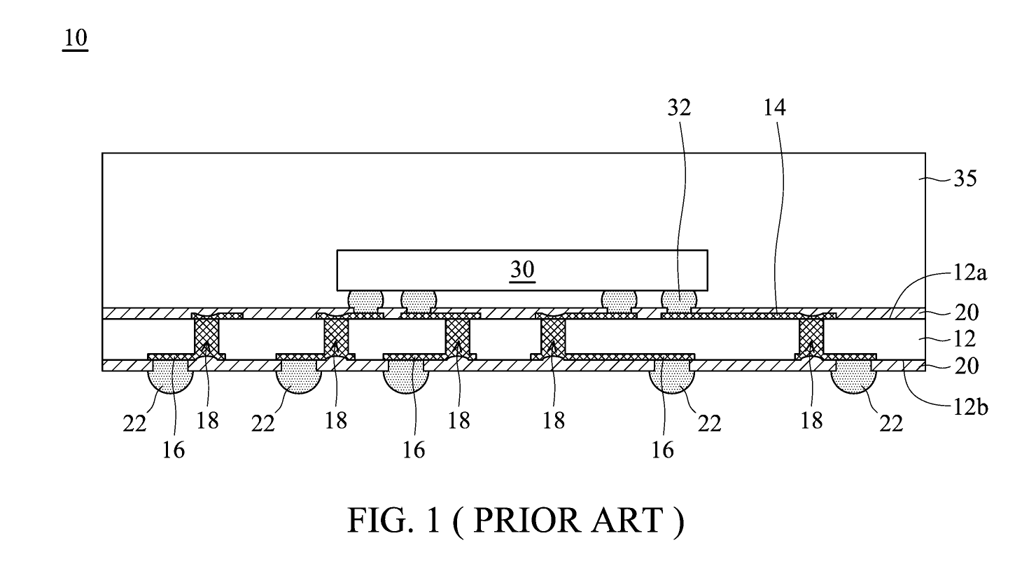

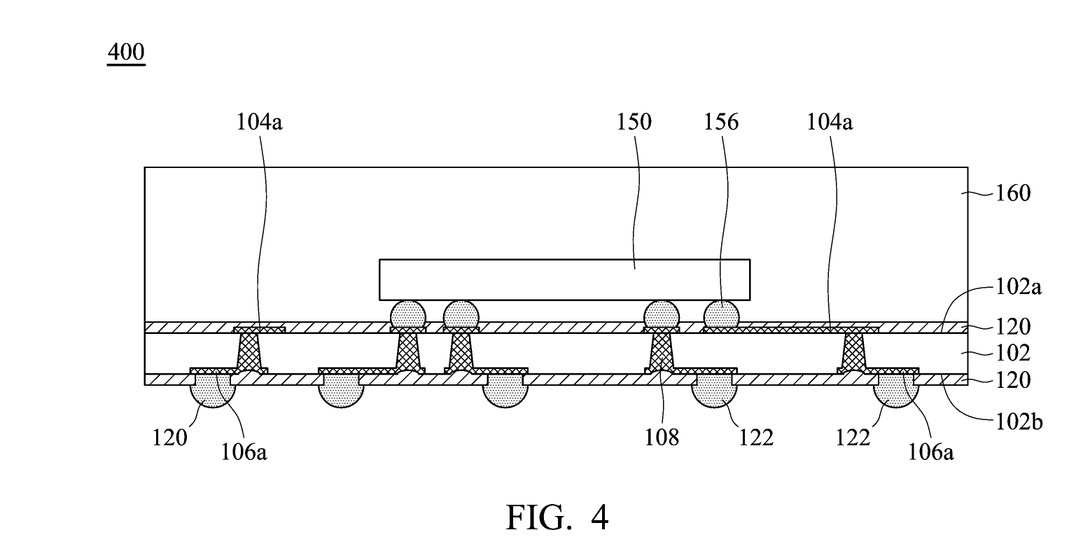

FIG. 4 shows a cross-sectional schematic representation of a package structure in accordance with another embodiment of the invention, wherein like elements are identified by the same reference numbers as in FIG. 1, and thus are omitted for clarity. The difference between the FIG. 4 and FIG. 3 is that a solder bump 156 is formed on the chip of FIG. 4. Compared with the solder bumps 156, the narrow metal pillar bumps 152 may be used in a finer pitch structure, without bridging shorts, and other problems such as no-uniform bump heights.

In this embodiment, the solder bump 156 is formed on the vias 108, and thus a shorter trace route and better electrical performance is obtained. Furthermore, the widths of the plurality of vias 108 are gradually increased from the first surface 102a to the second surface 102b. Because the flat-shaped surface of the first patterned metal layer 104a is provided, there is no need to form a pre-solder in the opening 123 and on the first patterned metal layer 104a.

From the above description, the metal pillar bumps 152 (in FIG. 3E) or the solder bumps 156 (in FIG. 4) are formed on the vias 108, and thus compared with prior art, a shorter trace route and better electrical performance is obtained. The vias 108 in the substrate 102 is formed by irradiation by the laser light from the second surface 102a, thus the widths of the plurality of vias 108 are gradually increased from the first surface 102a to the second surface 102b. The dimple problem in FIG. 2 is solved by providing the flat-shaped surface of first patterned metal layer 104a. Therefore, compared with prior art, there is no need to form the pre-solder in the invention. Thus, the manufacturing cost and time can be reduced.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A package structure, comprising:
a substrate, wherein the substrate has a first surface and a second surface, and a first pattern metal layer is formed on the first surface, and a second patterned metal layer is formed on the second surface, and the substrate has a plurality of vias formed therein, wherein the first patterned metal layer is electrically connected to the second patterned metal layer through the plurality of vias, and the widths of the plurality of vias are gradually increased from the first surface to the second surface;
a chip formed on the first surface of the substrate, wherein the chip has a plurality of bumps facing the first surface of the substrate, and the bumps are formed on the vias and are electrically connected to the first patterned metal layer; and
a molding material is formed on the substrate and the chip, wherein the chip is covered by the molding material.

2. The package structure as claimed in claim 1, wherein the bumps comprise solder bumps or metal pillar bumps.

3. The package structure as claimed in claim 1, wherein the vias are formed by a laser drilling method.

4. The package structure as claimed in claim 1, wherein the substrate comprises paper phenolic resin, composite epoxy, polyimide resin or glass fiber.

5. The package structure as claimed in claim 1, wherein the first patterned metal layer and the second patterned metal layer each individually comprise copper, alumina, nickel, gold or combinations thereof.

6. The package structure as claimed in claim 1, wherein the vias comprise copper, alumina, nickel, gold or combinations thereof.

7. The package structure as claimed in claim 1, further comprising:
an anti-soldering insulation layer individually formed on the first patterned metal layer and the second patterned metal layer, wherein the anti-soldering insulation layer has a plurality of openings to individually expose the first patterned metal layer and the second patterned metal layer.

8. The package structure as claimed in claim 7, wherein the bumps of the chip are formed on the exposed first patterned metal layer.

9. The package structure as claimed in claim 7, wherein the exposed first patterned metal layer has a flat-shaped surface.

10. The package structure as claimed in claim 7, further comprising:
a second bump formed on the exposed second patterned metal layer.

11. A method for fabricating the package structure, comprising:
providing a substrate, wherein the substrate has a first surface and a second surface, and a first pattern metal layer is formed on the first surface, and a second patterned metal layer is formed on the second surface, and the substrate has a plurality of vias formed therein, wherein the first patterned metal layer is electrically connected to the second patterned metal layer through the plurality of vias, and the widths of the plurality of vias are gradually increased from the first surface to the second surface;
forming a chip on the fist surface of the substrate, wherein the chip has a plurality of bumps facing the first surface of the substrate, and the bumps are formed on the vias and are electrically connected to the first patterned metal layer; and
forming a molding material on the substrate and the chip, wherein the chip is covered by the molding material.

12. The method for fabricating the package structure as claimed in claim 11, wherein the vias are formed by a laser drilling method.

13. The method for fabricating the package structure as claimed in claim 11, wherein the bumps comprise solder bumps or metal pillar bumps.

14. The method for fabricating the package structure as claimed in claim 11, before forming the chip, further comprising:
individually forming an anti-soldering insulation layer on the first patterned metal layer and the second patterned metal layer, wherein the anti-soldering insulation layer has a plurality of openings to expose the first patterned metal layer and the second patterned metal layer.

15. The method for fabricating the package structure as claimed in claim 14, wherein the exposed first patterned metal layer has a flat-shaped surface.

16. The method for fabricating the package structure as claimed in claim 14, wherein there is no pre-solder formed on the exposed first patterned metal layer.

17. The method for fabricating the package structure as claimed in claim 14, wherein a second bump is formed on the exposed second patterned metal layer.

18. The method for fabricating the package structure as claimed in claim 11, wherein the first patterned metal layer and the second patterned metal layer each individually comprise copper, alumina, nickel, gold or combinations thereof.

19. The method for fabricating the package structure as claimed in claim 11, wherein the vias comprise copper, alumina, nickel, gold or combinations thereof.
